(19) United States
(12) Patent Application Publication
(10) Pub. No.: US 2025/0385107 A1
(43) Pub. Date: Dec. 18, 2025

(54) WAFER PROCESSING APPARATUS

(71) Applicant: Samsung Electronics Co., Ltd., Suwon-si (KR)

(72) Inventor: Jeong-Bo YANG, Suwon-si (KR)

(21) Appl. No.: 18/966,885

(22) Filed: Dec. 3, 2024

(30) Foreign Application Priority Data
Jun. 13, 2024 (KR) 10-2024-0077258

(51) Int. Cl. H01L 21/67; B08B 3/08

(52) U.S. Cl. CPC H01L 21/67057; B08B 3/08

(57) ABSTRACT

A wafer processing apparatus may include a bath configured to accommodate wafers, a liquid manifold configured to supply a liquid into the bath, gas manifolds extending in a second direction parallel to one side of each wafer, disposed below the wafers, and each gas manifold configured to inject a gas in a third direction toward the wafers through an injection hole, and the gas manifolds including a first gas manifold disposed corresponding to a first wafer and a second gas manifold disposed corresponding to a second wafer, a gas supply source configured to supply the gas to the gas manifolds and a plurality of flow controllers including a first flow controller configured to control a flow rate of gas to the first gas manifold and a second flow controller configured to control a flow rate of gas to the second gas manifold.

### CROSS-REFERENCE TO RELATED APPLICATION

This application claims priority to Korean Patent Application No. 10-2024-0077258, filed in the Korean Intellectual Property Office on June 13, 2024, the entire contents of which are hereby incorporated by reference.

### BACKGROUND

### Field

The present disclosure relates to a wafer processing apparatus accommodating a plurality of wafers and a liquid used for processing the plurality of wafers.

### Desription of Related Art

A wafer processing apparatus for performing steps of processing a surface of a substrate, such as surface cleaning, thin film etching, etc. on a batch of a plurality of wafers may be used for manufacturing semiconductors.

When a liquid used for processing a plurality of wafers is supplied to the wafer processing apparatus, gas for facilitating the liquid supply may be supplied to the wafer processing apparatus. However, there are problems in that the gas is not uniformly dispersed over the plurality of wafers in the wafer processing apparatus, or an etching volume for each wafer is not regulated, depending on the arrangement of a gas supply device that supplies the gas.

### SUMMARY

In order to solve one or more problems (e.g., the problems described above and/or other problems not explicitly described herein), the present disclosure provides a wafer processing apparatus.

The problems to be solved by the present disclosure are not limited to those described above, and other problems not mentioned can be clearly understood by those skilled in the art from the description of the disclosure below.

A wafer processing apparatus may include a bath configured to accommodate a plurality of wafers including a first wafer and a second wafer with the first wafer spaced apart from the second wafer in a first direction, a liquid manifold configured to supply a liquid used for processing the wafer into the bath, a plurality of gas manifolds extending in a second direction parallel to one side of each wafer of the plurality of wafers, disposed below the plurality of wafers, and each gas manifold configured to inject gas in a third direction toward the plurality of wafers through an injection hole of a respective gas manifold, and the plurality of gas manifold including a first gas manifold disposed corresponding to the first wafer and a second gas manifold disposed corresponding to the second wafer, a gas supply source configured to supply the gas to the plurality of gas manifolds, and a plurality of flow controllers including a first flow controller configured to control a flow rate of gas to be supplied from the gas supply source to the first gas manifold and a second flow controller configured to control a flow rate of gas to be supplied to the second gas manifold.

A wafer processing apparatus may include a bath configured to accommodate a plurality of wafers including a first wafer and a second wafer with the first wafer and the second wafer spaced apart from each other in a first direction, a liquid manifold configured to supply a liquid used for processing the plurality of wafers into the bath, a plurality of gas manifolds extending in a second direction parallel to one side of each wafer of the plurality of wafers, disposed below the plurality of wafers, and each gas manifold configured to inject a gas in a third direction toward the plurality of wafers through an injection hole of a respective manifold, and the plurality of gas manifolds including a first gas manifold disposed corresponding to the first wafer and a second gas manifold disposed corresponding to the second wafer, a plurality of gas supply sources configured to supply the gas to the plurality of gas manifolds and a plurality of flow controllers including a first flow controller configured to control a flow rate of gas to be supplied from a first gas supply source of the plurality of gas supply sources to the first gas manifold and a second flow controller configured to control a flow rate of gas to be supplied from a second gas supply source of the plurality of gas supply sources to the second gas manifold, wherein the first flow controller may include a first pipe flow controller configured to control a flow rate of the gas to be supplied to a first supply pipe extending along a side of the bath and connected to a first end of the first gas manifold, and a second pipe flow controller configured to control a flow rate of the gas to be supplied to a second supply pipe connected to a second end of the first gas manifold, and the first gas supply source is configured to supply the gas to the first gas manifold through the first supply pipe and the second gas supply source is configured to supply the gas to the first gas manifold through the second supply pipe.

According to various aspects of the present disclosure, the amount of gas supplied to each gas manifold of a plurality of gas manifolds corresponding to a respective wafer of a plurality of wafers can be regulated such that the problem of a plurality of wafers being processed non-uniformly due to factors such as different liquid temperature and/or concentration, different gas pressure, etc. depending on the location in the bath can be prevented.

According to various aspects of the present disclosure, two or more gas manifolds may be disposed between one side of the bath and the plurality of wafers and the spray pressure of the gas manifold adjacent to the one side of the bath is greater than the spray pressure of the gas manifolds disposed between each of the plurality of wafers such that the problem of vortices of gas and/or liquid caused by the sidewall of the bath can be alleviated or prevented.

According to various aspects of the present disclosure, the liquid manifolds are provided corresponding to each wafer of the plurality of wafers and the liquid manifolds corresponding to each of the wafers are individually controlled such that the plurality of wafers can be processed more uniformly.

Various and beneficial advantages and effects of embodiments of the inventive concept are not limited to those described above, and can be more easily understood in the course of describing specific aspects of the present disclosure.

### BRIEF DESCRIPTION OF THE DRAWINGS

FIG. 1 is a view illustrating a wafer processing apparatus;

FIG. 2 is a block diagram illustrating the wafer processing apparatus according to various embodiments of the present disclosure;

FIG. 3A is a plan view of the wafer processing apparatus according to various embodiments of the present disclosure;

FIG. 3B is a view illustrating a modification of the wafer processing apparatus in FIG. 3A;

FIG. 4A is a cross-sectional view of the wafer processing apparatus taken along the line I-I' in FIG. 3A;

FIGS. 4B and 4C are cross-sectional views illustrating modifications of the wafer processing apparatus of FIG. 4A;

FIG. 5A is a cross-sectional view taken along the line II-II' in FIG. 3A;

FIGS. 5B to 5E are cross-sectional views illustrating modifications of the wafer processing apparatus of FIG. 5A;

FIGS. 6A to 6D are views illustrating a gas exhaust unit of a wafer processing apparatus according to various embodiments of the present disclosure; and

FIGS. 7A and 7B are views illustrating a gas exhaust unit of a wafer processing apparatus according to various embodiments of the present disclosure.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim. Thus, the expression a “first” element or a “second” element may refer to any one of a plurality of the elements. For example, a “first wafer” or a “second wafer” may refer to any one arbitrarily selected from among a plurality of wafers, and a “first gas nozzle” or a “second gas nozzle” may refer to any one arbitrarily selected from among a plurality of gas nozzles.

Throughout the specification, when a component is described as "including" a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. Additionally, when elements that convey fluid are connected together it will be understood that they are "fluidly connected" such that a liquid or gas can flow, or be passed, from one item to the other.

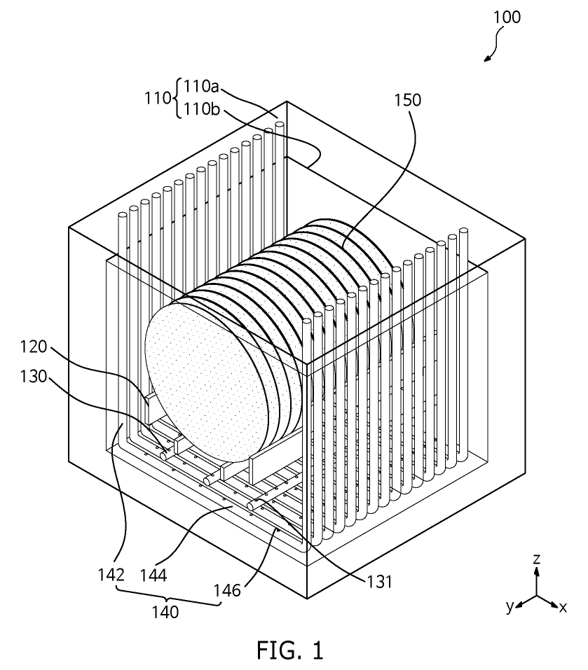

Hereinafter, various aspects of the present disclosure will be described with reference to FIGS. 1 to 7. The same reference numerals may refer to the same components throughout the description.

FIG. 1 is a view illustrating a wafer processing apparatus 100. The wafer processing apparatus 100 may include a bath 110, a support 120, a plurality of liquid manifolds (e.g., liquid nozzles 130), and a plurality of gas supply units (e.g., gas exhaust units 140). Various types of processing such as etching or cleaning may be performed on a plurality of wafers 150 in the bath 110 using the wafer processing apparatus 100. This allows the etching of a specific pattern on the surfaces of the plurality of wafers 150 or the removal of oxides, organic substances, metal impurities, etc. from the surface of the plurality of wafers 150.

The bath 110 may accommodate therein the plurality of wafers 150. The plurality of wafers 150 may be spaced apart from each other at predetermined intervals (e.g., 5 mm). Each wafer of the plurality of wafers 150 may be spaced apart at an equal interval in a specific direction (e.g., in y-direction). The support 120 may support the plurality of wafers 150 and may have features for spacing the wafers 150 such as notches or protrusions to hold a wafer 150 at a fixed location.

The bath 110 may accommodate a liquid used for wet processing the plurality of wafers 150. For example, the bath 110 may accommodate a liquid including an etchant for etching the plurality of wafers 150 or a cleaning solution for cleaning the plurality of wafers 150.

The bath 110 may include an outer bath 110a and an inner bath 110b. The outer bath 110a may form an outer structure of the bath 110, and the inner bath 110b may be disposed inside the outer bath 110a to accommodate the liquid that is in contact with the plurality of wafers 150. The space between the outer bath 110a and the inner bath 110b may serve as a drain for the liquid overflowing from the inner bath 110b.

Additionally, the wafer processing apparatus 100 may further include an upper cover that covers an open upper side of the bath 110. Alternatively, the bath 110 may be configured as a chamber without an open upper side.

The support 120 may support the plurality of wafers 150. The support 120 may be formed in any shape that allows the plurality of wafers 150 to be stably positioned while being processed in the bath 110. For example, one or both ends of the support 120 may penetrate at least a portion of the bath 110 (e.g., the inner bath 110b) to be fixed. The shape and/or arrangement of the support 120 may be adjusted to suit the size and shape of the plurality of wafers 150. The support 120 may be disposed at various angles and positions so that the plurality of wafers 150 can be immersed in the liquid accommodated in the bath 110, and may fix the plurality of wafers 150 in position using various support mechanisms.

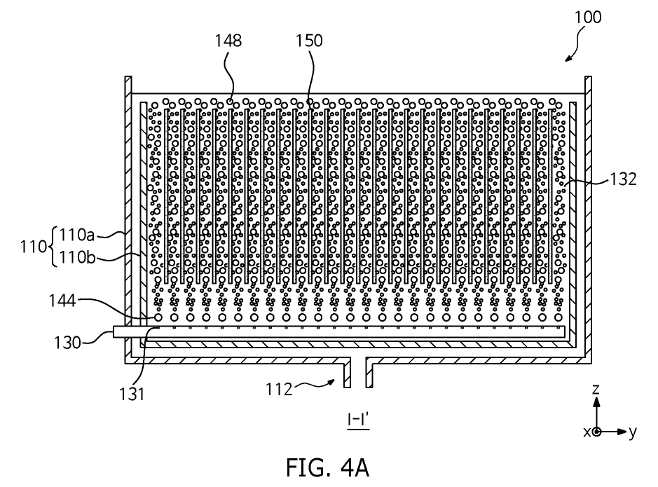

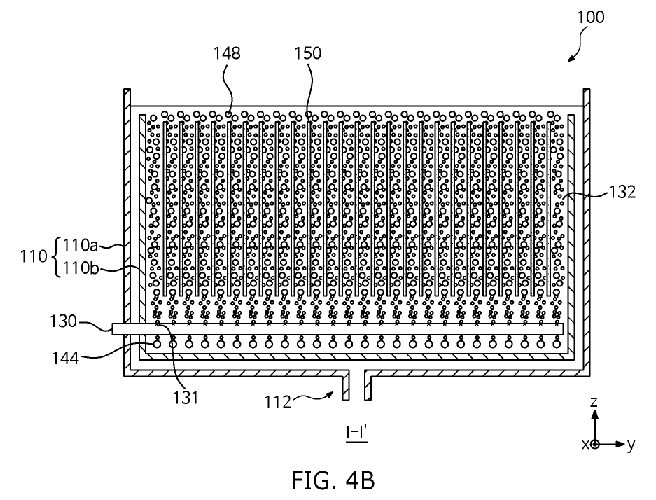

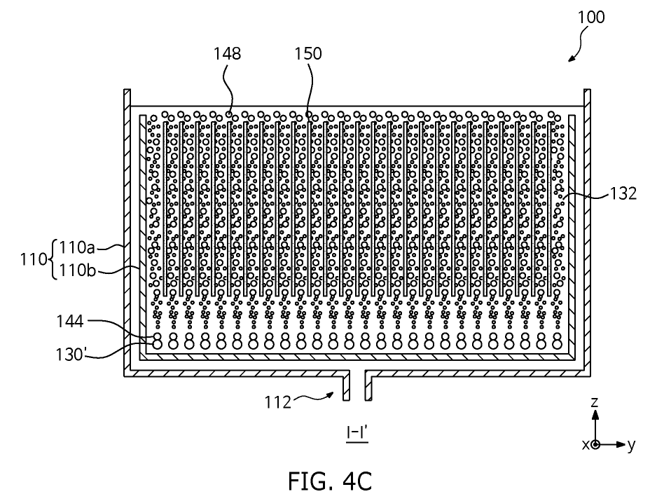

The liquid nozzles 130 may supply the liquid to be accommodated in the bath 110 into the bath 110. The liquid nozzles 130 may be disposed to cross a plurality of gas nozzles 144. For example, the liquid nozzles 130 may be disposed to cross the plurality of gas nozzles 144 perpendicularly. Alternatively, the liquid nozzles 130 may extend in a direction parallel to the plurality of gas nozzles 144. Various shapes and arrangements of the liquid nozzles 130 will be described in detail below with reference to FIGS. 4A to 4C.

The liquid nozzles 130 may supply the liquid into the bath 110 in any direction. The liquid nozzles 130 may supply the liquid using a plurality of supply holes 131 formed on the liquid nozzles 130. For example, the plurality of supply holes 131 may supply the liquid in +z-direction in FIG. 1. Additionally or alternatively, the liquid nozzles 130 may supply the liquid in x-direction. Each supply hole 131 of the plurality of supply holes 131 may be formed at locations corresponding to a corresponding wafer 150 of the plurality of wafers 150, but locations are not limited thereto, and any number of supply holes 131 may be formed on the liquid nozzle 130.

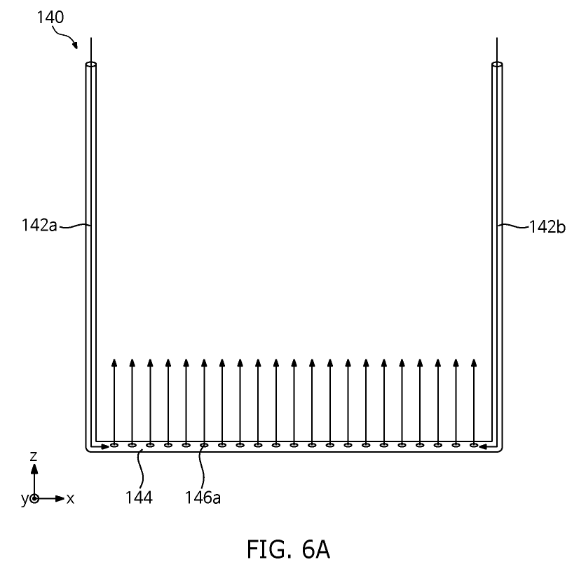

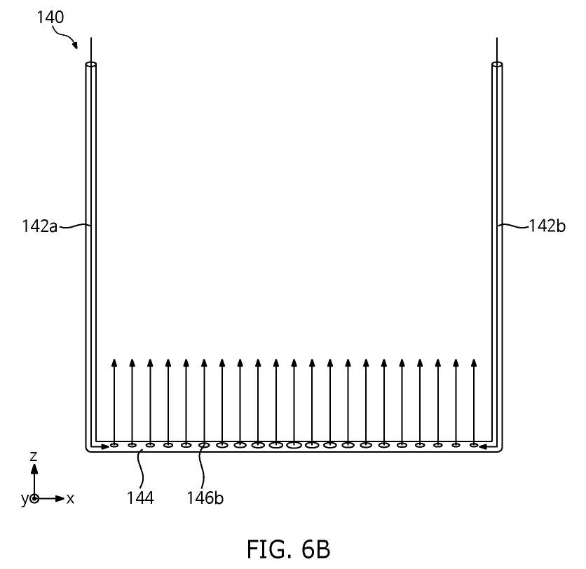

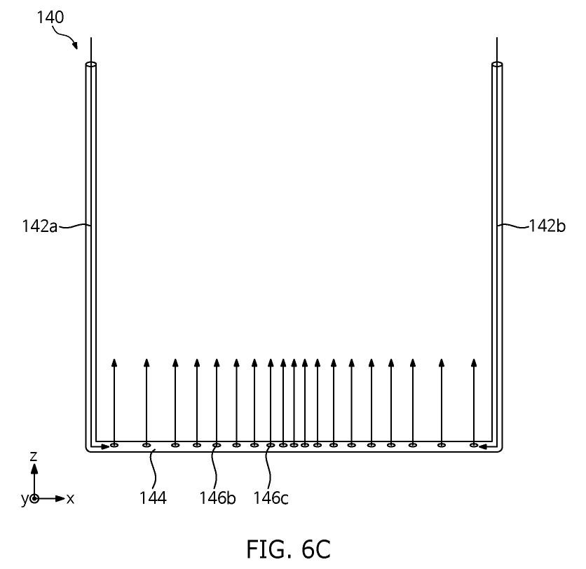

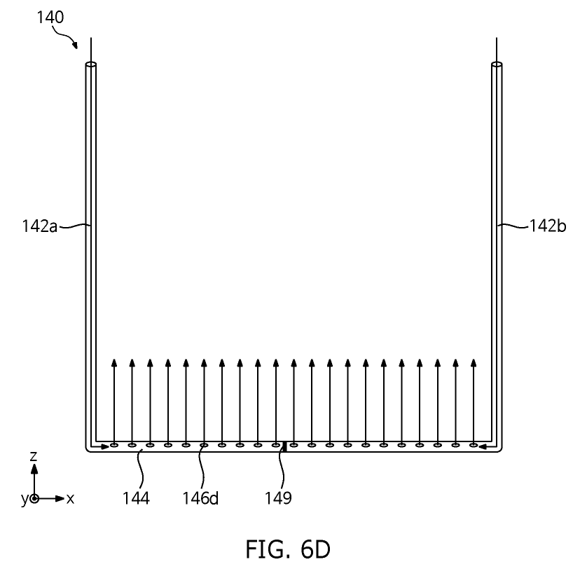

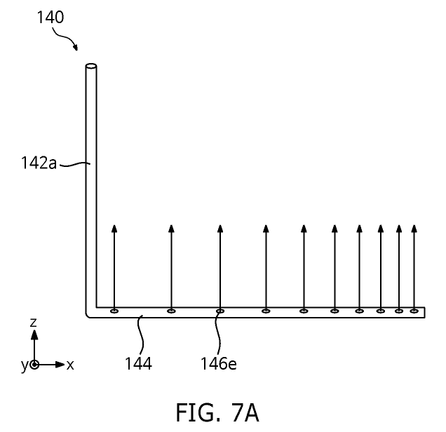

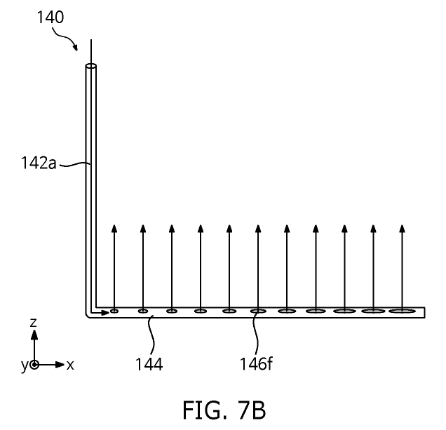

The gas exhaust unit 140 may include a supply pipe 142 for supplying gas, and a gas manifold (e.g., gas nozzle 144). The gas exhaust unit 140 may receive gas from a gas supply source (not illustrated) through the supply pipe 142 and discharge gas using the gas nozzle 144. The plurality of gas nozzles 144 may spray gas in the direction (e.g., z-direction) of the plurality of wafers 150 using a plurality of injection holes 146. Additionally or alternatively, the plurality of gas nozzles 144 may include injection holes for spraying the gas in y-direction. Various aspects of spraying the gas with the plurality of gas nozzles 144 will be described in detail below with reference to FIG. 6 or 7.

That gas exhaust unit 140 may be formed of a material that includes QUARTZ, polytetrafluoroethylene (PTFE), polyetheretherketone (PEEK), perfluoroalkoxy (PFA), etc.

Each gas nozzle 144 of the plurality of gas nozzles 144 may extend in a direction (e.g., x-direction) parallel to one side of a corresponding wafer 150 of the plurality of wafers 150 (e.g., a front surface of a wafer). At least some gas nozzles 144 of the plurality of gas nozzles 144 may be disposed corresponding to a wafer 150 of the plurality of wafers 150 (e.g., a gas nozzle 144 may have a corresponding wafer 150). For example, at least some gas nozzles 144 of the plurality of gas nozzles 144 may extend in a direction (e.g., x-direction) parallel to one side of a corresponding wafer 150 of the plurality of wafers 150 and be disposed between corresponding adjacent wafers 150 of the plurality of wafers 150 in a direction (e.g., y-direction) in which the wafers 150 of the plurality of wafers 150 are spaced apart from each other.

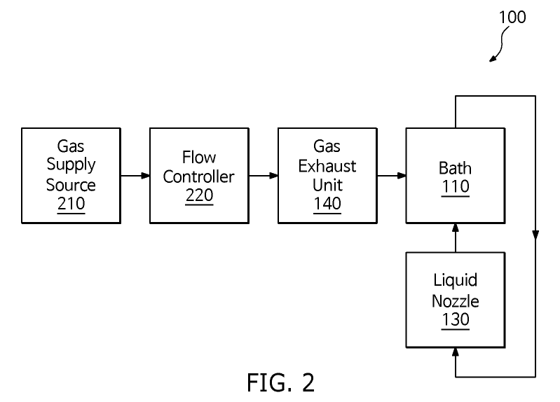

Note that the number of the gas exhaust units 140 and wafers 150 illustrated in FIG. 1 is an example for the convenience of description, and aspects are not limited thereto. In addition, the illustrations of the gas supply source and a flow controller included in the wafer processing apparatus 100 are omitted in FIG. 1 for the convenience of description, but they will be described in detail below with reference to FIG. 2, etc.

FIG. 2 is a block diagram illustrating the wafer processing apparatus 100 according to various embodiments of the present disclosure. The wafer processing apparatus 100 may further include a gas supply source 210 and a flow controller 220.

The gas supply source 210 may supply the gas to the gas exhaust units 140. The gas supplied from the gas supply source 210 may include inert gas (e.g., He, Ne, Ar, N₂, etc.).

The flow controller 220 may control a flow rate of the gas to be supplied from the gas supply source 210 to the gas exhaust units 140. For example, the flow controller 220 may monitor the pressure, etc. of the gas delivered to the gas exhaust units 140 and measure and regulate the flow rate of the gas.

The gas exhaust units 140 may spray the gas into the bath 110. For example, a first gas exhaust unit 140 may spray the gas in the direction of a corresponding first wafer.

The liquid to be accommodated in the bath 110 may be supplied from the liquid nozzles 130, and the liquid may circulate between the bath 110 and the liquid nozzles 130. The gas sprayed by the gas exhaust units 140 may accelerate the circulation of the liquid.

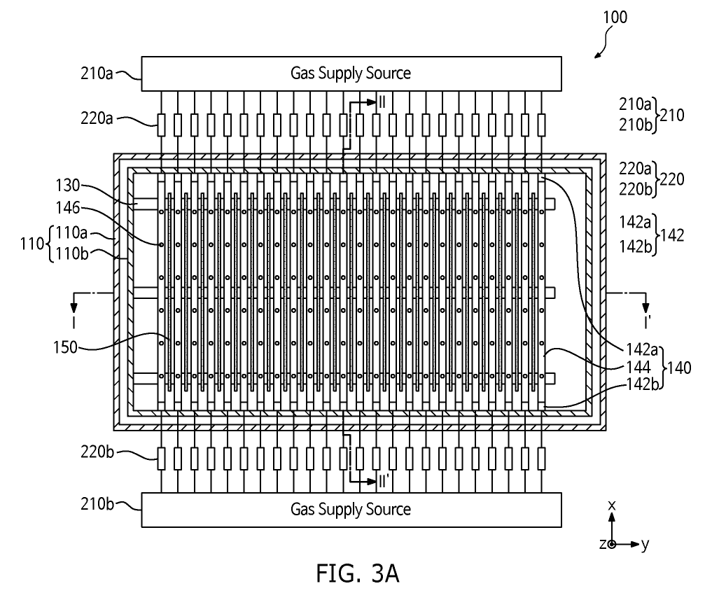

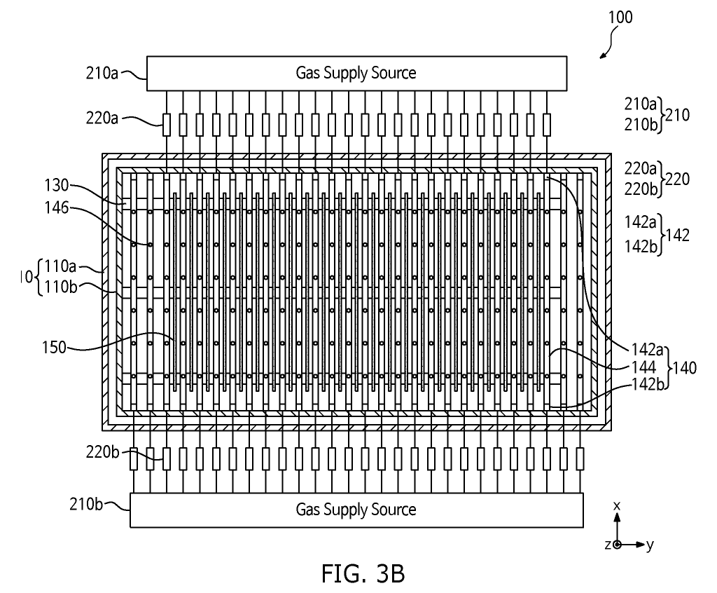

FIG. 3A is a plan view of the wafer processing apparatus 100 according to various embodiments of the present disclosure. The plurality of gas exhaust units 140 may include a plurality of supply pipes 142 and the plurality of gas nozzles 144. The plurality of supply pipes 142 may include a first supply pipe 142a connected to a first end of a gas nozzle 144 and a second supply pipe 142b connected to a second end of the gas nozzle 144. Alternatively, any one of the first supply pipe 142a and the second supply pipe 142b may be omitted, and any one of the first supply pipe 142a and the second supply pipe 142b may be connected to a first end of the gas nozzle 144 and the second end of the gas nozzle 144 may be blocked. This will be described in detail below with reference to FIGS. 7A and 7B.

The flow controller 220 may include a first pipe flow controller 220a and a second pipe flow controller 220b. The wafer processing apparatus 100 may include a plurality of flow controllers 220 which each flow controller 220 having a respective first pipe flow controller 220a to form a plurality of first pipe flow controllers 220a and a respective second pipe flow controller 220b to form a plurality of second pipe flow controllers 220b. The plurality of first pipe flow controllers 220a for controlling the flow rate of the gas to be supplied from the first gas supply source 210a to a plurality of first supply pipes 142a may be connected to the plurality of first supply pipes 142a, and the plurality of second flow controllers 220b for controlling the flow rate of the gas to be supplied from the second gas supply source 210b to a plurality of second supply pipes 142b may be connected to the plurality of second supply pipes 142b. Each first pipe flow controller 220a may be connected to a respective first supply pipe and each second pipe flow controller 220b may be connected to a second supply pipe For example, using a plurality of flow controllers 220, it is possible to use each individual flow controller 220 to individually control the amount of gas supplied to each of the gas nozzles 144, as well as the amount of gas supplied to a plurality of supply pipes 142a and 142b connected to one gas nozzle 144. Each flow controller 220 of the plurality of flow controllers 220 may include a mass flow controller (MFC). Accordingly, the problem of the plurality of wafers 150 being processed non-uniformly due to factors such as different liquid temperature and/or concentration, different gas pressure, etc. depending on the location in the bath 110 can be prevented, and even if the wafers 150 are processed non-uniformly, it is possible to individually control a plurality of gas supply sources 210 in the subsequent process to ensure that the plurality of wafers 150 are processed uniformly.

The first gas supply source 210a and the second gas supply source 210b may be integrally configured or there may be a plurality of gas supply sources separately connected to each first flow pipe controller 220a of the plurality of first pipe flow controllers 220a and each second pipe flow controller 220b of the plurality of second pipe flow controllers 220b. It is illustrated that the first pipe flow controller 220a and the second pipe flow controller 220b of a flow controller 220 are separate from each other, but aspects are not limited thereto, and the first pipe flow controller 220a and the second pipe flow controller 220b may be integrally configured into the flow controller 220 and separately control the flow rate of the gas supplied to each of the first supply pipe 142a and the second supply pipe 142b.

As illustrated in FIG. 3A, the plurality of gas exhaust units 140 may include a first group of gas exhaust units 140 with gas exhaust units 140 of the group disposed between respective adjacent wafers 150 of the plurality of wafers 150 in the direction (e.g., y-direction) in which the plurality of wafers 150 are spaced apart from each other, and a gas exhaust unit 140 or a second group of gas exhaust units, which may be referred to as end gas exhaust units to differentiate them from gas exhaust units 140 included in the first group, disposed between one side of the bath 110 and the plurality of wafers 150 in that direction. For example, gas exhaust units 140 of the plurality of gas exhaust units 140 and wafers 150 of the plurality of wafers 150 may be alternately disposed in a specific direction (e.g., in y-direction), in which the number of the plurality of gas exhaust units 140 may be greater (e.g., one more) than the number of the plurality of wafers 150. Alternatively, some of the plurality of gas exhaust units 140 may be omitted.

A distance between the respective centers of the plurality of wafers 150 in the first direction and a distance between the respective centers of the plurality of gas exhaust units 140 in the first direction may be substantially the same (or the same).

FIG. 3B is a view illustrating a modification of the wafer processing apparatus 100 in FIG. 3A.

Referring to FIG. 3B, unlike FIG. 3A, two or more end gas exhaust units including two or more gas nozzles, which may be referred to as end gas nozzles or end gas manifolds, may be disposed between one side of the bath 110 and the plurality of wafers 150. For example, two or more gas nozzles may be disposed between the first wafer positioned in the y-direction among the plurality of wafers 150 and one side of the bath 110 facing the first wafer. Additionally or alternatively, two or more gas nozzles may be disposed between the last wafer positioned in the y-direction among the plurality of wafers 150 and the one side of the bath 110 facing the last wafer.

The spray pressure of the gas nozzle or of the gas nozzles, adjacent to the one side of the bath 110 may be greater than the spray pressure of the gas nozzles in the first group that are disposed between the plurality of wafers 150. Accordingly, it is possible to reduce the problem of vortices of gas and/or liquid caused by the sidewall of the bath 110.

FIG. 4A is a cross-sectional view of the wafer processing apparatus taken along the line I-I' in FIG. 3A. The liquid nozzles 130 may be disposed to cross a plurality of gas nozzles 144. The liquid nozzles 130 may be disposed below the plurality of gas nozzles 144.

The liquid nozzles 130, which may include a plurality of supply holes 131, may supply a liquid 132 such as an etchant for etching the wafers 150 or a cleaning solution for cleaning the wafers 150 into the bath 110. The liquid nozzles 130 may penetrate one side of the bath 110 to extend from an interior of the bath 110 to an exterior of the bath 110. For example, the liquid 132 supplied into the bath 110 may include an SC1 solution, a phosphoric acid solution, a tetramethylammonium hydroxide (TMAH), etc., but is not limited thereto. FIG. 4A illustrates that the plurality of supply holes 131 of the liquid nozzle 130 are formed with each supply hole of a liquid nozzle 130 at a location corresponding to a respective gas nozzle 144 of the plurality of gas nozzles 144 in the y-direction, but aspects are not limited thereto. For example, the supply holes 131 may be disposed (or formed) to position each supply hole between respective adjacent gas nozzles 144 of the plurality of gas nozzles 144 in the y-direction. In addition, the plurality of supply holes 131 may include any number of supply holes.

Bubbles 148 may be generated in the liquid 132 as the plurality of gas nozzles 144 spray the gas in the direction of the plurality of wafers 150. The bubbles 148 generated from each gas nozzle 144 of the plurality of gas nozzles 144 may move toward the upper portion of the bath 110 through the space between the wafers 150 or the space between the plurality of wafers 150 and the bath 110.

The bubbles 148 generated from the plurality of gas nozzles 144 may accelerate the movement of the liquid supplied from the liquid nozzles 130 toward the upper portion of the bath 110.

FIGS. 4B and 4C are cross-sectional views illustrating modifications of FIG. 4A.

Referring to FIG. 4B, the liquid nozzle 130 may be disposed above the plurality of gas nozzles 144. The liquid nozzle 130 may be disposed below the plurality of gas nozzles 144 as illustrated in FIG. 4A or may be disposed above the plurality of gas nozzles 144 as illustrated in FIG. 4B, depending on the type, concentration, density, etc. of the liquid 132 used for processing the plurality of wafers 150.

Referring to FIG. 4C, unlike in FIG. 4A, the wafer processing apparatus 100 may include a plurality of liquid nozzles 130' corresponding to the plurality of gas nozzles 144 and extending in a direction parallel to the plurality of gas nozzles 144. The plurality of liquid nozzles 130' may penetrate one side (e.g., one of two opposite sides in the x-direction) of the bath 110. FIG. 4C illustrates that the plurality of liquid nozzles 130' are disposed below the plurality of gas nozzles 144, but aspects are not limited thereto. For example, each liquid nozzle 130' of the plurality of liquid nozzles 130' may be disposed on the side (e.g., on the side in the y-direction) of a corresponding gas nozzle 144 of the plurality of gas nozzles 144 or may be disposed above a corresponding gas nozzle 144 of the plurality of gas nozzles 144.

The liquid supplied from each liquid nozzle 130' of the plurality of liquid nozzles 130' may be individually controlled through separate flow controllers (not illustrated). Thus, each gas nozzle 144 of the plurality of gas nozzles 144 and each liquid nozzle 130' of the plurality of liquid nozzles 130' may be individually controlled so that the plurality of wafers 150 are processed more uniformly.

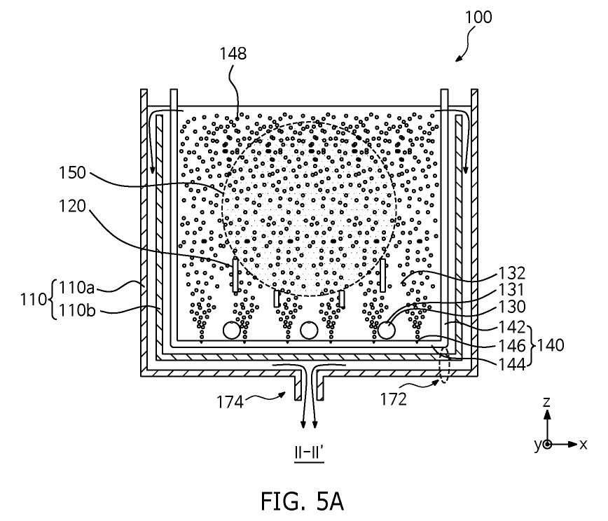

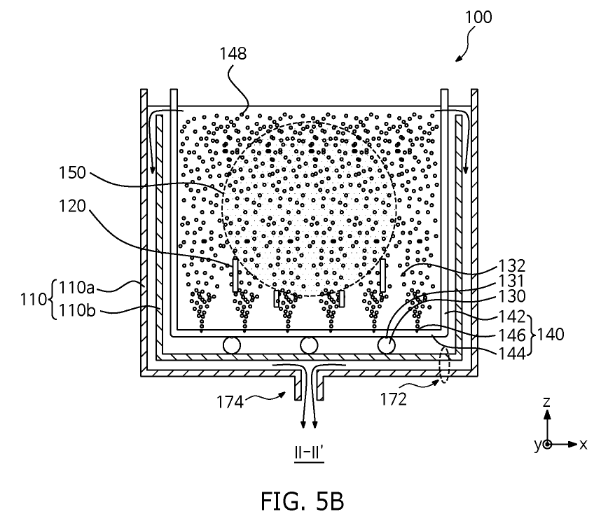

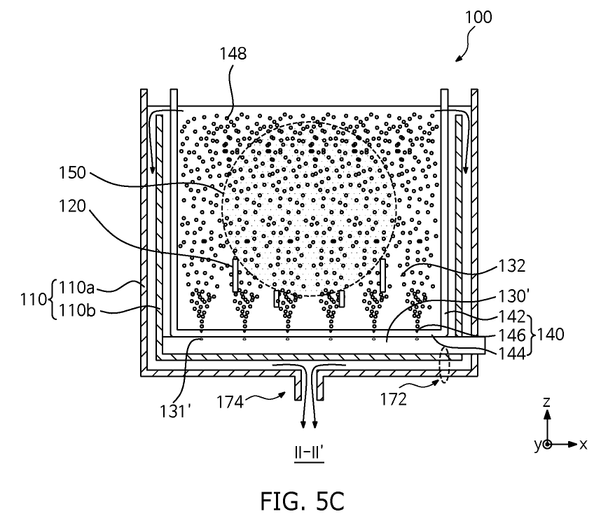

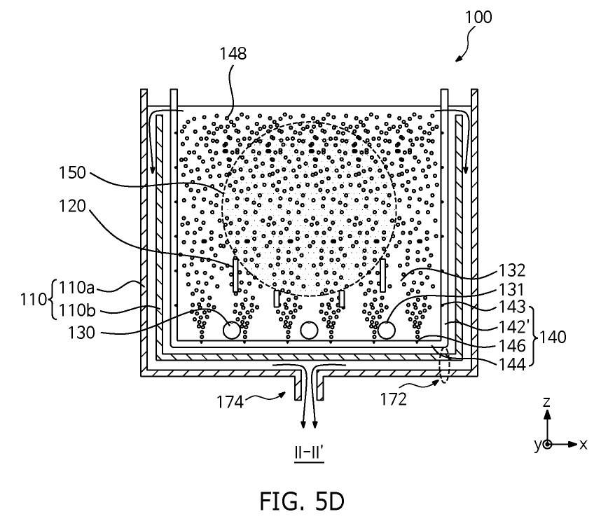

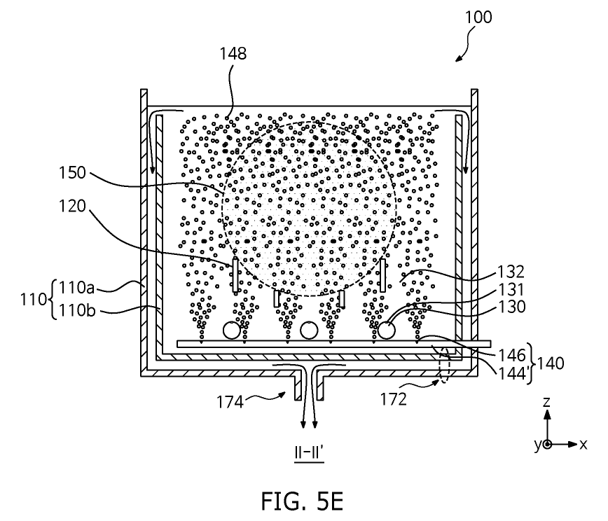

FIG. 5A is a cross-sectional view taken along the line II-II' in FIG. 3A.

The supply pipe 142 may extend along the side of the bath 110 to be connected to the gas nozzle 144.

The gas nozzle 144 may have one or more injection holes 146 formed on it. The gas nozzle 144 may spray the gas in the direction (e.g., +z-direction) of the wafer 150 through the one or more injection holes 146.

The bath 110 may include a drain 174 through which the liquid 132 is drained, and the liquid 132 drained through the drain 174 may be supplied back to the liquid nozzle 130. For example, the liquid accommodated in the bath 110 may overflow from the upper portion the inner bath 110b into the space 172 between the outer bath 110a and the inner bath 110b, and the overflowing liquid may be drained through the drain 174 and be selectively subjected to a purification process, etc. and supplied back into the inner bath 110b through the liquid nozzle 130. For example, the liquid from the drain 174 may pass through a filter, may be heated or cooled, or otherwise processed prior to the liquid being returned to the liquid nozzle 130. Accordingly, the liquid used for processing the plurality of wafers 150 can be supplied in a circulating manner, and the concentration, temperature gradient, etc. of the liquid accommodated in the inner bath 110b can be maintained constant.

FIGS. 5B to 5E are cross-sectional views illustrating modifications of FIG. 5A.

Referring to FIG. 5B, the liquid nozzles 130 may be disposed above the plurality of gas nozzles 144, and this may correspond to the arrangement of the liquid nozzle 130 illustrated in FIG. 4B. Referring to FIG. 5C, a liquid nozzle 130' may correspond to a gas nozzle 144 and extend in a direction parallel to the gas nozzle 144. The arrangement of the liquid nozzle 130' in FIG. 5C may correspond to the arrangement of the liquid nozzle 130' illustrated and described above with reference to FIG. 4C. FIG. 5C illustrates that each supply hole 131' of the plurality of supply holes 131' of the liquid nozzle 130' is formed at a location corresponding to a corresponding injection hole 146 of the plurality of injection holes 146 of the gas nozzle 144 in the x-direction, but aspects are not limited thereto. For example, the plurality of supply holes 131' may be disposed with each supply hole 131' located between corresponding adjacent injection holes 146 of the plurality of injection holes 146 in the x-direction. In addition, the plurality of supply holes 131' may include any number of supply holes.

Referring to FIG. 5D, the supply pipe 142 may further include one or more injection holes 143 for spraying the gas in the direction of the wafers 150.

Referring to FIG. 5E, instead of being connected to the supply pipe 142 as illustrated in FIG. 5A, etc., a gas nozzle 144' may penetrate through at least one side (e.g., at least one of the two opposite sides in the x-direction) of the bath 110, and the gas supply source (e.g., the gas supply source 210 in FIG. 3A) may be connected to a protruding end of the gas nozzle 144' penetrating the bath 110.

FIGS. 6A to 6D are views illustrating the gas exhaust unit 140 in isolation. The supply pipe 142 of the gas exhaust unit 140 may include a first supply pipe 142a connected to a first end of the gas nozzle 144 and a second supply pipe 142b connected to the other end of the gas nozzle 144. The first supply pipe 142a may be connected to a first pipe flow controller for controlling the flow rate of the gas to be supplied to the first supply pipe 142a, and the second supply pipe 142b may be connected to a second pipe flow controller for controlling the flow rate of the gas to be supplied to the second supply pipe 142b, respectively.

Referring to FIG. 6A, the gas nozzle 144 may include a plurality of injection holes 146a for spraying the gas in the direction (e.g., z-direction) of the wafers. Each injection hole 146a of the plurality of injection holes 146a may have substantially the same (or the same) cross-sectional area and may be disposed at substantially the same (or the same) intervals.

The gas spray pressure from the gas nozzle 144 to the outside of the gas nozzle 144 may decrease along the gas nozzle 144 at locations farther away from the supply pipes 142a and 142b. For example, the pressure of the gas sprayed from an injection hole 146a located at the center of the gas nozzle 144 may be less than the pressure of the gas sprayed from an injection hole near the end of the gas nozzle 144. To address this issue, the shape or arrangement of the plurality of injection holes 146a may be modified so that the deviation in the flow rate of the sprayed gas according to the location of the injection holes on the gas nozzle 144 may be reduced or eliminated.

For example, referring to FIG. 6B, a plurality of injection holes 146b formed closer to the center of the gas nozzle 144 than other injection holes 146b may have a larger cross-sectional area than the other injection holes 146b formed farther away from the center of the gas nozzle 144, so that substantially the same (or the same) flow rate of the gas per unit time is sprayed from each injection hole. For example, the plurality of injection holes 146b may be formed with a diameter of 0.01 mm to 5 mm.

Referring to FIG. 6C, a plurality of injection holes 146c formed at locations closer to the center of the gas nozzle 144 than other injection holes 146c may be formed at a narrower interval between adjacent injection holes 146c than the interval between adjacent injection holes 146c of the other injection holes 146c. Accordingly, the deviation in the flow rate of the sprayed gas according to the locations of the injection holes on the gas nozzle 144 may be reduced or eliminated.

FIG. 6B illustrates a configuration in which the injection holes have different cross-sectional areas, and FIG. 6C illustrates a configuration in which the injection holes are spaced at different intervals, but aspects are not limited thereto. The injection holes may have different cross-sectional areas and also be at different intervals so as to reduce or eliminate the deviation in the flow rate of the sprayed gas according to the locations of the injection holes on the gas nozzle 144.

Referring to FIG. 6D, the gas nozzle 144 may include a separating membrane 149 that separates the gas flowing into the gas nozzle 144 through the first supply pipe 142a and the gas flowing into the gas nozzle 144 through the second supply pipe 142b from each other. The separating membrane 149 may block the flow of gas in the gas nozzle 144. The inclusion of the separating membrane 149 in the gas nozzle 144 ensures that each injection hole 146d positioned between the first supply pipe 142a and the separating membrane 149 of the plurality of injection holes 146d sprays only the gas flowing into the gas nozzle 144 through the first supply pipe 142a. Accordingly, it is possible to individually and easily control the wafer dispersion in the right and left direction with reference to the separating membrane 149 with ease.

The separating membrane 149 may be disposed at the center of the gas nozzle 144 but is not limited thereto and may be disposed at various locations in the gas nozzle 144.

FIGS. 7A and 7B are views illustrating the gas exhaust unit 140 according to various embodiments of the present disclosure. The supply pipe 142 may be connected to one end of the gas nozzle 144 and the other end of the gas nozzle 144 may be closed.

Referring to FIG. 7A, a plurality of injection holes 146e formed on the gas nozzle 144 at locations farther away from the supply pipe 142 may be formed at a narrower interval than injection holes 146e formed on the gas nozzle 144 at locations closer to the supply pipe 142. Accordingly, it is possible to reduce or eliminate the deviation in the flow rate of the sprayed gas according to the locations of the injection holes on the gas nozzle 144.

Referring to FIG. 7B, each of a plurality of injection holes 146f formed at a location farther away from the supply pipe 142 may be formed with a larger cross-sectional area than injection holes 146f formed at locations closer to the supply pipe. Accordingly, it is possible to reduce or eliminate the deviation in the flow rate of the sprayed gas according to the locations of the injection holes on the gas nozzle 144.

FIG. 7A illustrates a configuration in which the injection holes are at different intervals, and FIG. 7B illustrates a configuration in which the injection holes have different cross-sectional areas, but aspects are not limited thereto. The plurality of injection holes may have different cross-sectional areas and also be spaced at different intervals so as to reduce or eliminate the deviation in the flow rate of the sprayed gas according to the locations of the injection holes on the gas nozzle 144.

The present inventive concept is not limited to the aspects described above and the accompanying drawings, and various forms of substitution, modification, and change will be possible by those of ordinary skill in the art without departing from the technical idea of the inventive concept.

1. A wafer processing apparatus, comprising:
a bath configured to accommodate a plurality of wafers comprising a first wafer and a second wafer with the first wafer spaced apart from the second wafer in a first direction;
a liquid manifold configured to supply a liquid for processing the plurality of wafers into the bath;
a plurality of gas manifolds extending in a second direction parallel to one side of each wafer of the plurality of wafers, disposed below the plurality of wafers, and each gas manifold of the plurality configured to inject a gas in a third direction toward the plurality of wafers through an injection hole of a respective gas manifold, and the plurality of gas manifolds comprising a first gas manifold disposed to correspond to the first wafer and a second gas manifold disposed to correspond to the second wafer;
a gas supply source configured to supply the gas to the plurality of gas manifolds; and
a plurality of flow controllers comprising a first flow controller configured to control a flow rate of gas to be supplied from the gas supply source to the first gas manifold, and a second flow controller configured to control a flow rate of gas to be supplied to the second gas manifold.

2. The wafer processing apparatus according to claim 1, wherein
the first flow controller is configured to control a flow rate of the gas to be supplied to the first gas manifold through a supply pipe connected to the first gas manifold, and
the supply pipe extends along a side of the bath and is connected to the first gas manifold.

3. The wafer processing apparatus according to claim 2, wherein the supply pipe comprises one or more injection holes formed therein to inject the gas in a direction toward the first wafer.

4. The wafer processing apparatus according to claim 2, wherein
the supply pipe is a first supply pipe of a plurality of supply pipes, wherein the plurality of supply pipes comprises the first supply pipe connected to a first end of the first gas manifold and a second supply pipe connected to a second end of the first gas manifold, and
the first flow controller comprises a first pipe flow controller configured to control a flow rate of the gas to be supplied to the first supply pipe and a second pipe flow controller configured to control a flow rate of the gas to be supplied to the second supply pipe.

5. The wafer processing apparatus according to claim 4,
wherein the first gas manifold comprises a separating membrane configured to separate the gas flowing into the first gas manifold through the first supply pipe and the gas flowing into the first gas manifold through the second supply pipe from each other.

6. The wafer processing apparatus according to claim 4, wherein
the first gas manifold comprises a plurality of injection holes formed therein to inject the gas in the third direction, and
a first injection hole formed at a location closer to a center of the first gas manifold than a second injection hole has a larger cross-sectional area than the second injection hole.

7. The wafer processing apparatus according to claim 4, wherein
the first gas manifold comprises a plurality of injection holes formed therein to inject the gas in the third direction, and
a first distance between a first injection hole and a second injection hole adjacent to the first injection hole is less than a second distance between a third injection hole and a fourth injection hole adjacent to the third injection hole, wherein the first injection hole and the second injection hole are formed at locations closer to a center of the first gas manifold than the location of the third injection hole and the fourth injection hole.

8. The wafer processing apparatus according to claim 2, wherein
the supply pipe is connected to a first end of the first gas manifold, and
a second end of the first gas manifold is closed.

9. The wafer processing apparatus according to claim 8, wherein
the first gas manifold comprises a plurality of injection holes formed therein to inject the gas in the third direction, and
a first injection hole formed at a location farther away from the supply pipe than a second injection hole has a larger cross-sectional area than the second injection hole.

10. The wafer processing apparatus according to claim 8, wherein
the first gas manifold comprises a plurality of injection holes formed therein to inject the gas in the third direction, and
a first distance between a first injection hole and a second injection hole adjacent to the first injection hole is less than a second distance between a third injection hole and a fourth injection hole adjacent to the third injection hole, wherein the first injection hole and the second injection hole are formed at locations closer to a center of the first gas manifold than the location of the third injection hole and the fourth injection hole.

11. The wafer processing apparatus according to claim 1, wherein the plurality of gas manifolds comprises a group of gas manifolds with each gas manifold of the group disposed between respective adjacent wafers of the plurality of wafers in the first direction and an end gas manifold disposed between a side of the bath and the plurality of wafers in the first direction.

12. The wafer processing apparatus according to claim 11, wherein the end gas manifold is a first end gas manifold of a plurality of end gas manifolds disposed between the side of the bath and the plurality of wafers.

13. The wafer processing apparatus according to claim 12, wherein a spray pressure of an end gas manifold that is adjacent to the side of the bath is greater than a spray pressure of each gas manifold disposed between adjacent wafers of the plurality of wafers.

14. The wafer processing apparatus according to claim 1, wherein the liquid manifold is disposed to cross the plurality of gas manifolds.

15. The wafer processing apparatus according to claim 1, wherein the liquid manifold is a first liquid manifold of a plurality of liquid manifolds, wherein each liquid manifold of the plurality of liquid manifolds corresponds to a corresponding gas manifold of the plurality of gas manifolds and the plurality of liquid manifolds extend in a direction parallel to the plurality of gas manifolds.

16. The wafer processing apparatus according to claim 1, wherein the liquid manifold penetrates through a side of the bath.

17. The wafer processing apparatus according to claim 1, wherein
the bath comprises a drain configured to drain a liquid in the bath, and
the wafer processing apparatus is configured to purify liquid drained through the drain and supply a resulting purified liquid to the liquid manifold.

18. The wafer processing apparatus according to claim 1, wherein the liquid comprises an etchant for etching a wafer in the bath or a cleaning solution for cleaning a wafer in the bath.

19. The wafer processing apparatus according to claim 1, wherein
the bath is configured to arrange each wafer of the plurality of wafers to be spaced apart from each other such that a distance between centers of wafers adjacent to each other is a first distance,
each gas manifold of the plurality of gas manifolds are disposed to be spaced apart from an adjacent gas manifold such that a distance between centers of gas manifolds adjacent to each other is a second distance, and
the first distance and the second distance are the same as each other.

20. A wafer processing apparatus, comprising:
a bath configured to accommodate a plurality of wafers comprising a first wafer and a second wafer with the first wafer and the second wafer spaced apart from each other in a first direction;
a liquid manifold configured to supply a liquid used for processing the plurality of wafers into the bath;
a plurality of gas manifolds extending in a second direction parallel to one side of each wafer of the plurality of wafers, disposed below the plurality of wafers, and each gas manifold of the plurality of gas manifolds configured to inject a gas in a third direction toward the plurality of wafers through an injection hole of a respective gas manifold, and the plurality of gas manifolds comprising a first gas manifold disposed corresponding to the first wafer and a second gas manifold disposed corresponding to the second wafer;
a plurality of gas supply sources configured to supply the gas to the plurality of gas manifolds; and
a plurality of flow controllers comprising a first flow controller configured to control a flow rate of gas to be supplied from the gas supply source to the first gas manifold, and a second flow controller configured to control a flow rate of gas to be supplied to the second gas manifold, wherein
the first flow controller comprises a first pipe flow controller configured to control a flow rate of the gas to be supplied to a first supply pipe extending along a side of the bath and connected to a first end of the first gas manifold, and a second pipe flow controller configured to control a flow rate of the gas to be supplied to a second supply pipe connected to a second end of the first gas manifold, and
the plurality of gas supply source comprises a first gas supply source configured to supply the gas to the first gas manifold through the first supply pipe and a second gas supply source configured to supply the gas to the first gas manifold through the second supply pipe.
